(19) United States
(12) Patent Application Publication
(10) Pub. No.: US 2003/0054671 A1
(43) Pub. Date: Mar. 20, 2003

(54) Method for forming insulation film and method for manufacturing semiconductor device

(76) Inventor: Shigeru Fujita, Kanagawa (JP)

Correspondence Address: SONNENSCHEIN NATH & ROSENTHAL, P.O. BOX 061080, WACKER DRIVE STATION, CHICAGO, IL, 60606-1080, US

(21) Appl. No.: 10/149,344

(22) PCT Filed: Oct. 18, 2001
(86) PCT No.: PCT/JP01/09141

(30) Foreign Application Priority Data
Oct. 18, 2000 (JP) 2000-317539

(51) Int. Cl. H01L 21/31; H01L 21/4763; H01L 21/469

(52) U.S. Cl. 438/787; 438/623

(57) ABSTRACT

In case of depositing a silicon oxide film and a silicate glass film, which are used as inter-layer insulating films by high density plasma CVD method, deposition temperature is set in the range from 400 to 680° C., preferably in the range from 400 to 600° C., furthermore preferably in the range from 450 to 550° C. Thereby, it is aimed to improve reliability of the insulating films by controlling plasma damage while controlling expansion of contact holes caused by a hydrofluoric acid process in pretreatment prior to a process for burying the contact holes with burying material after the contact holes have been formed in the insulating film.

### TECHNICAL FIELD

The invention relates to a deposition method of an insulating film and a manufacturing method of a semiconductor device, which are especially suitable for applying to manufacture of a semiconductor device comprising a process for depositing an insulating film by High Density Plasma (HDP)-CVD process.

### BACKGROUND ART

With recent progression in quality of semiconductor devices, it is required to lower process temperature. Additionally, with progression in integration scale of DRAM, it is required to decrease the cell area. As the cell area is decreased and process temperature is lowered, it has become difficult to adopt a process, which has been conventionally applied to an inter-layer insulating film of DRAM, for performing a high temperature reflow to boro-phospho silicate glass (BPSG) to bury and accomplishing its planarization. On the other hand, recently, a plasma CVD process, called HDP-CVD, in which burying ability is improved by contributing a sputtering factor during deposition has been developed. The process is mainly being applied for an inter-layer insulating film of A1 wiring at present.

In case that a silicon oxide film deposited by the HDP-CVD process is applied to an inter-layer insulating film for polycrystalline silicon of DRAM, after contact holes have been formed in the inter-layer insulating film and before the contact holes are buried with plug burying material (usually a phosphor-doped polycrystalline silicon is used), pretreatment by hydrofluoric acid process is performed to remove native oxide on the base surface at the bottom portion of the contact holes. However, it is afraid that the pretreatment makes the contact holes expand. Therefore, it is required to deposit the silicon oxide film at a temperature as high as possible (about 700° C.). This is because when deposition is performed at a high temperature, a lower wet etching rate can be obtained for hydrofluoric acid. A typical deposition condition according to a conventional HDP-CVD process is described hereinbelow.

Top RF power: 1300 W

Side RF power: 3100 W

Bias RF power: 3500 W

Flow rate of SiH₄ gas: 70 sccm

Flow rate of O₂ gas: 130 sccm

Flow rate of Ar gas: 130 sccm

Pressure: 0.67 Pa (5 mTorr)

When the inter-layer insulating film for polycrystalline silicon of DRAM is considered in the height direction (vertical direction to a substrate), it is located at near position to transistors. The application of a plasma process to a deposition of the inter-layer insulating film may cause plasma damage to the transistors. So reliability evaluation of an oxide film of a capacitor TEG (Test Element Group) was performed, and the obtained evaluation result was remarkably bad as explained below.

In FIG. 1, compared are Q_{bd} evaluation result of a silicon oxide film deposited by O₃-TEOS CVD method, that is a conventional nonplasma process using Ozone (O₃) and tetra-ethyloxysilane (also called tetraethoxysilane) (TEOS) and that of a silicon oxide film deposited by HDP-CVD method under a conventional deposition condition. As is obvious from FIG. 1, the Q_{bd} evaluation result of the silicon oxide film deposited by HDP-CVD method under the conventional deposition condition for depositing at 700° C. is remarkably inferior to that of the silicon oxide film deposited by O₃-TEOS CVD method, and reliability is remarkably low. This is a serious problem because it causes a variation of threshold voltage of, especially, p-channel MOS transistor with respect to characteristics of the device. Because of these reasons, HDP-CVD method under the conventional deposition condition cannot be applied to an inter-layer insulating film for polycrystalline silicon of DRAM as it is.

Though above-described PID (Plasma Induced Damage) can be generally improved by decreasing bias RF power, in experiments made by the present Inventor, regarding a decrease of bias RF power according to HDP-CVD process, no remarkable effect in decreasing PID was confirmed. In addition, it has been confirmed by an observation with a cross section SEM that a source of the damage was not a physical attack to a sample with an excess sputtering factor.

Therefore, a subject that the invention is to solve is to provide a depositing method of an insulating film which in case of depositing a silicon oxide film, or more generally an insulating film mainly consisting of silicon and oxygen by HDP-CVD method, in processes thereafter, can improve reliability of the insulating film by controlling its PID while controlling expansion of contact holes caused by a hydrofluoric acid process in pretreatment prior to a process for burying the contact holes with burying material after the contact holes have been formed in the insulating film, and a manufacturing method of a semiconductor device having a depositing process of such an insulating film.

On the other hand, in case of depositing an insulating film mainly consisting of a silicon oxide by HDP-CVD method, there is another process for burying burying material without performing the pretreatment after the contact holes have been formed in the insulating film. In this process, there is not a problem that the contact holes are expanded by a hydrofluoric acid process in the pretreatment prior to burying after the contact holes have been formed. However, even in such a case, it is required to prevent degassing from sidewall of contact holes caused by gas (mainly considered as hydrogen) that is incorporated into a film during deposition and prevent failures caused by this degassing.

Therefore, another subject that the invention is to solve is to provide a depositing method of an insulating film which in case of depositing an insulating film mainly consisting of a silicon oxide by HDP-CVD method can improve reliability of the insulating film by controlling its PID while controlling degassing from the sidewall of contact holes after the contact holes have been formed in the insulating film, and a manufacturing method of a semiconductor device having a deposition process of such an insulating film.

### DISCLOSURE OF INVENTION

Present Inventor has intensively researched to solve the above-described subject that the conventional technology has. Its outline is given below.

That is, when a silicon oxide film is deposited as an inter-layer insulating film by HDP-CVD method, contact holes are formed, and then the contact holes are buried with burying material, desirable deposition temperature differs according to the controlling of PID and the presence or absence of the pretreatment by wet etching using hydrofluoric acid. More specifically, in case the pretreatment is performed, in order to prevent contact holes from expanding caused by the pretreatment while controlling PID, it is required to set the upper limit of deposition temperature to 680° C. from a view of PID controlling and the lower limit to 400° C. from a view of keeping the wet etching rate lower and preventing the expansion of contact holes by the pretreatment. In order to more certainly obtain these effects, it is desirable to set the deposition temperature in the range from 400 to 600° C., more preferably, 500±50° C., that is, in the range from 450 to 550° C.

In case the pretreatment is not performed, in order to control PID and prevent degassing from sidewall of contact holes, it is required to set the upper limit of deposition temperature to 680° C. from a view of controlling PID and the lower limit to 300° C. or more from a view of preventing degassing from sidewall of the contact holes by reducing gas amount incorporated into a film during deposition. In order to obtain these effects more certainly, it is preferable to set deposition temperature in the range from 360 to 550° C.

The above-described is not limited to a silicon oxide film but can be also applied to silicate glass, and more generally, it can be applied to whole the insulating films mainly consisting of silicon oxide.

The invention has been made on the basis of the above researches.

According to the first invention of the invention, there is provided a depositing method of an insulating film for depositing an insulating film mainly consisting of a silicon oxide by high density plasma CVD method,

wherein deposition temperature is set in the range from 400 to 680° C.

According to the second invention of the invention, there is provided a depositing method for depositing an insulating film mainly consisting of a silicon oxide by high density plasma CVD method,

wherein deposition temperature of the insulating film is set in the range from 300 to 680° C.

According to the third invention of the invention, there is provided a manufacturing method of a semiconductor device, comprising the steps of:

depositing an insulating film mainly consisting of a silicon oxide by high density plasma CVD method; and

performing pretreatment to contact holes by wet etching after the contact holes have been formed in the insulating film,

wherein depositing temperature of the insulating film is set in the range from 400 to 680° C.

According to the fourth invention of the invention, there is provided a manufacturing method of a semiconductor device, comprising the steps of:

depositing an insulating film mainly consisting of a silicon oxide by high density plasma CVD method; and

forming contact holes in the insulating film,

wherein deposition temperature of the insulating film is set in the range from 300 to 680° C.

According to the first and third inventions of the invention, in order to sufficiently obtain the effect of controlling the expansion of contact holes caused by the pretreatment while controlling PID of an insulating film, which is generated during deposition, it is desirable to set deposition temperature in the range from 400 to 600° C., more preferably, from 450 to 550° C., and furthermore preferably, from 490 to 510° C.

According to the second and fourth inventions of the invention, in order to control PID of an insulating film, which is generated during deposition and more certainly obtain the effect of controlling degassing from sidewall of contact holes, it is preferable to set deposition temperature in the range from 360 to 550° C.

According to the invention, an insulating film mainly consisting of a silicon oxide is typically a silicon oxide film or a silicate glass film, and the silicate glass film is non-doped silicate glass (NSG) film, phospho silicate glass (PSG) film, fluorine silicate glass (FSG) film, boro silicate glass (BSG) film, boro-phospho silicate glass (BPSG) film, arsenic silicate glass (AsSG) film, and the like.

According to the invention, typically, contact holes are formed in an insulating film, native oxide is removed from the base surface at a bottom portion of the contact holes by performing pretreatment to the contact holes by wet etching, and then the contact holes are buried with burying material.

According to the invention, deposition temperature may be set basically by any method as far as there are no difficulties. However, typically, it can be performed by absorbing a substrate by electrostatic chuck and blowing a cooled helium gas on the back of the substrate.

Generating methods of plasma used in the high density plasma CVD process are Electron Cyclotron Resonance (ECR), Inductively Coupled Plasma (ICP), helicon wave plasma, and the like. Plasma density of the high density plasma is usually about 1×10¹¹ to 1×10¹³/cm³.

According to the first and third inventions of the invention constituted as described above, since deposition temperature of an insulating film is set to 680° C. or less, the generation of PID during deposition can be effectively controlled. In addition, since deposition temperature of an insulating film is set to 400° C. or more, good film quality can be obtained and wet etching rate can be kept sufficiently low.

According to the second and fourth inventions of the invention constituted as described above, since deposition temperature of an insulating film is set to 680° C. or less, the generation of PID during deposition can be effectively controlled. In addition, since deposition temperature of an insulating film is set to 300° C. or more, gas incorporated into a film during deposition can be sufficiently reduced and degassing can be effectively controlled in processes thereafter.

### BRIEF DESCRIPTION OF DRAWINGS

FIG. 1 is a schematic view for showing a Q_{bd} evaluation result of a silicon oxide film deposited by HDP-CVD method under a conventional deposition condition; FIG. 2 to FIG. 5 are cross-sectional views for explaining a manufacturing method of DRAM according to the first embodiment of the invention; FIG. 6 is a plan view for showing a state of chucking a silicon substrate by electrostatic chuck during deposition of a silicon oxide film by HDP-CVD method in a manufacturing method of DRAM according to the first embodiment of the invention; FIG. 7 is a schematic view for showing a Q_{bd} evaluation result of a silicon oxide film deposited by HDP-CVD method under a deposition condition according to the first embodiment of the invention; and FIG. 8 is a cross-sectional view for showing a structure of a capacitor TEG used for Q_{bd} evaluation shown in FIG. 7.

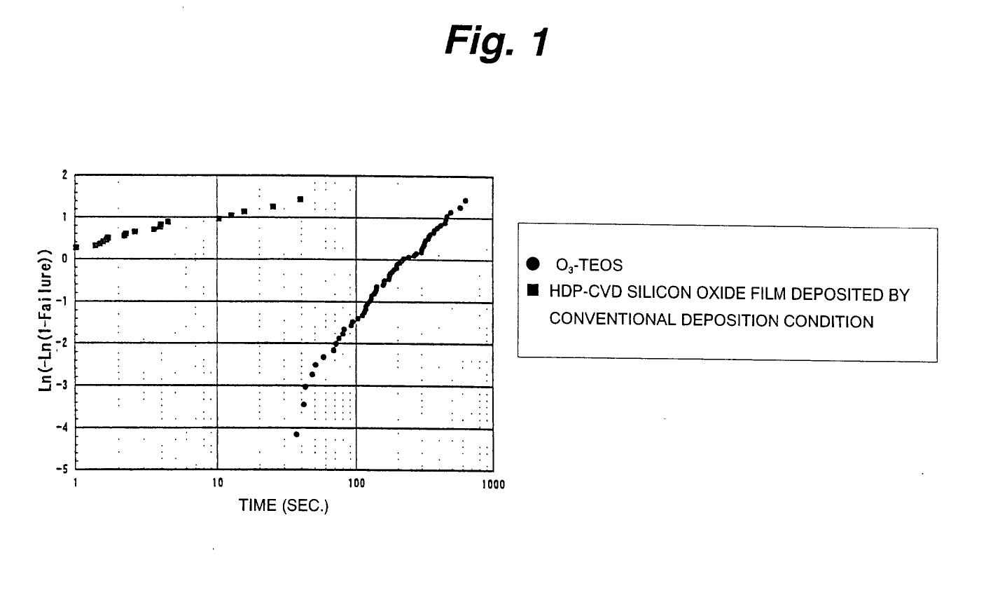

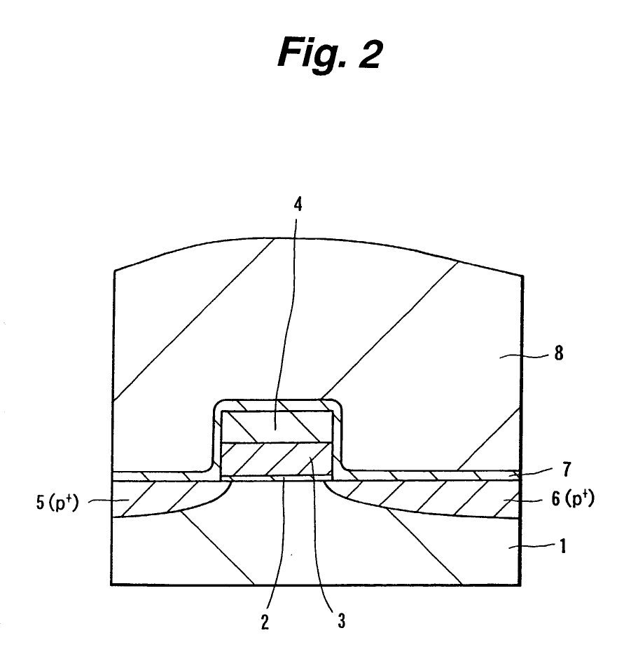

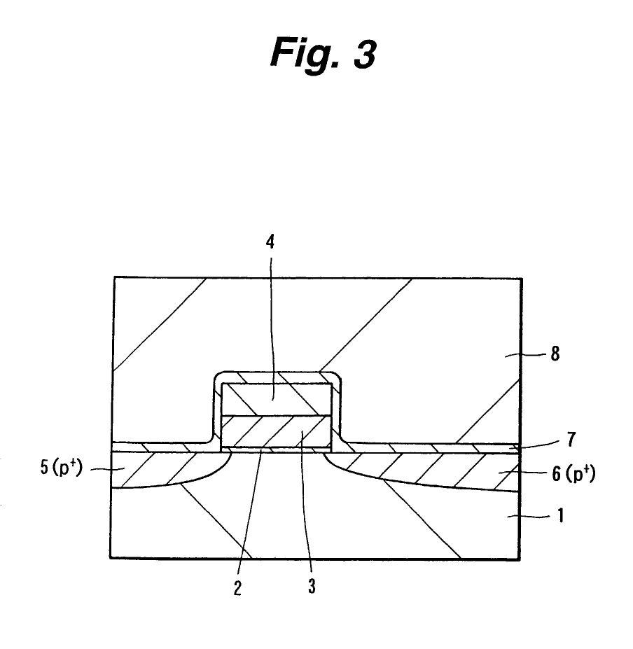

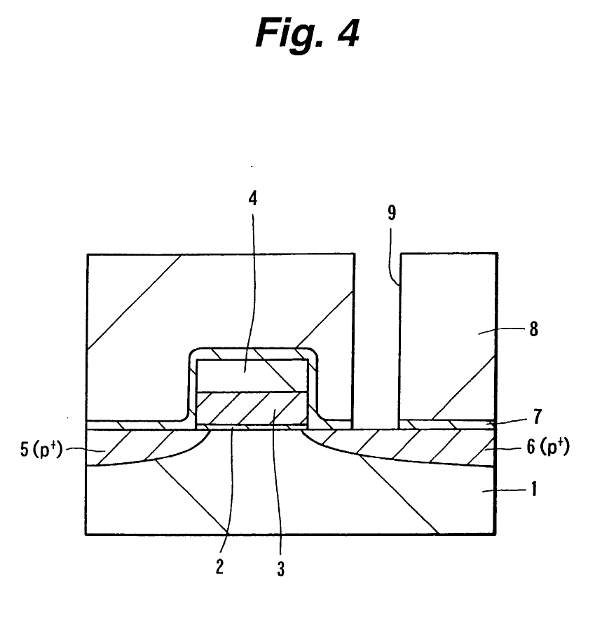

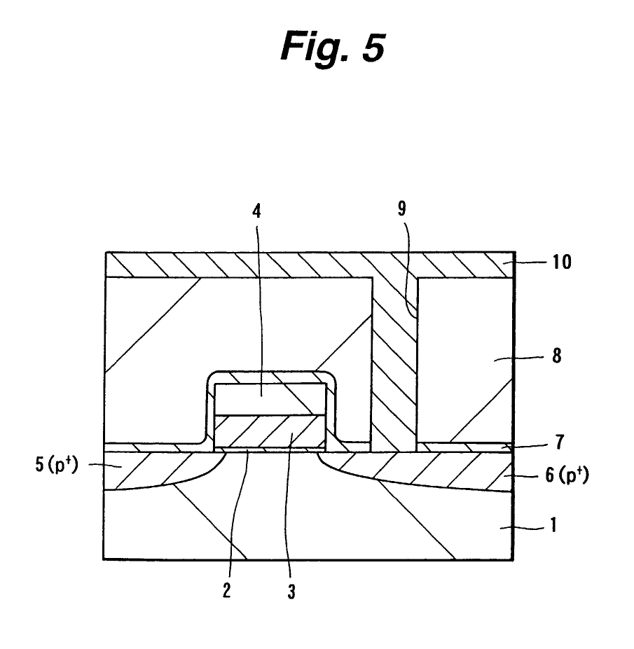

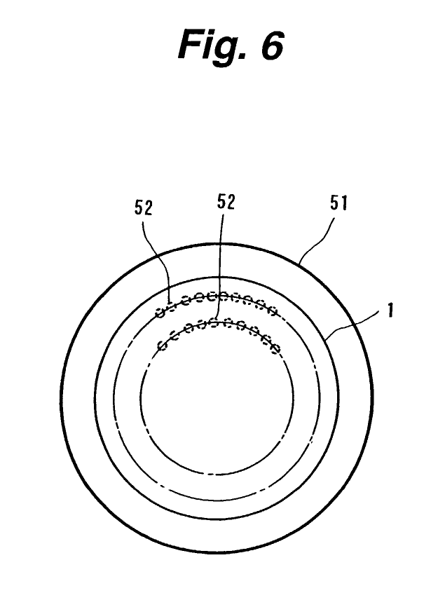

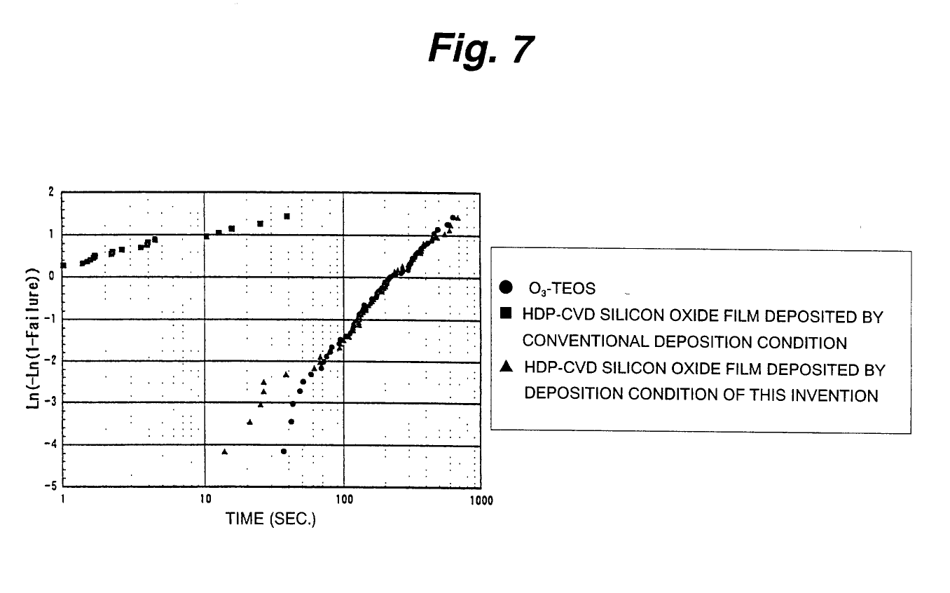

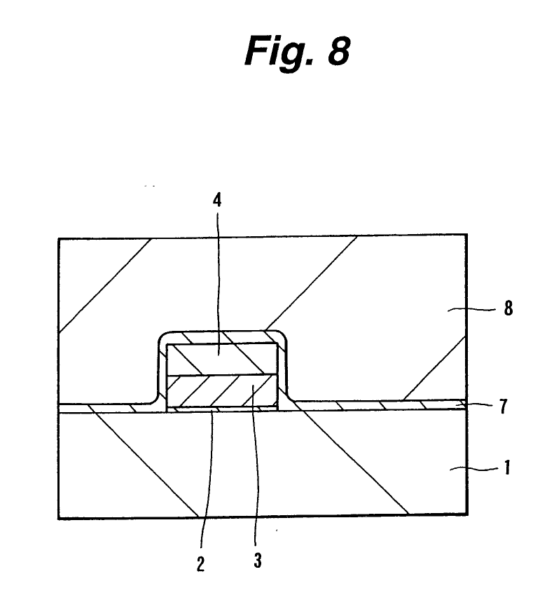

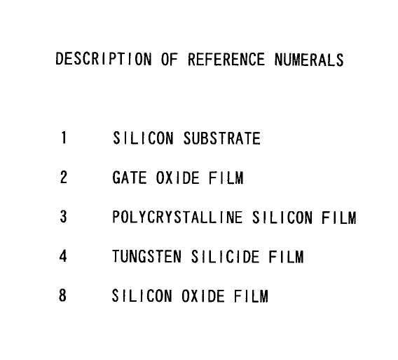

### BEST MODE FOR CARRYING OUT THE INVENTION

An embodiment of the invention is explained below with reference to the drawings.

A manufacturing method of DRAM according to an embodiment of the invention is shown in FIGS. 2 to 5. In the DRAM, though both an n-channel MOS transistor and a p-channel MOS transistor are used, FIGS. 2 to 5 show only a portion for forming a p-channel MOS transistor, and it will be explained hereinbelow only about the portion for forming a p-channel MOS transistor.

In the embodiment, as shown in FIG. 2, first, a device isolation area (not shown) has been formed on a silicon substrate 1, and n-well (not shown) is formed on the silicon substrate 1 by ion implantation, for example. Next, a gate oxide film 2 that consists of a silicon oxide film is formed on the surface of the n-well. A polycrystalline silicon film 3 is then deposited on the entire substrate surface by low pressure CVD method, for example. Further, the polycrystalline silicon film 3 is made to be low resistance by doping impurities by ion implantation, for example, and a tungsten silicide film 4, for example, is deposited on the polycrystalline silicon film 3 by sputtering method, for example. Next, these tungsten silicide film 4 and polycrystalline silicon film 3 are etched by reactive ion etching (RIE), for example, and patterned into a predetermined form, and a gate electrode of a polycide structure is formed. By performing ion implantation with boron (B) of a p-type impurity to the n-well using the gate electrode as a mask, a source region 5 and a drain region 6 of p⁺-type are formed in a self-alignment manner. Thereby a p-channel MOS transistor is formed. Then, a silicon nitride film 7 is deposited on the entire substrate surface by CVD method, for example.

Then, a silicon oxide film 8 is deposited as an inter-layer insulating film on the entire substrate surface by HDP-CVD method. ICP method is used as plasma generating method in the HDP-CVD method. An example of deposition condition is described hereinbelow.

Deposition temperature: 400 to 680° C.

Top RF power: 1300 W

Side RF power: 3100 W

Bias RF power: 3500 W

Flow rate of SiH₄ gas: 70 sccm

Flow rate of O₂ gas: 130 sccm

Flow rate of Ar gas 130 sccm

Pressure: 0.67 Pa (5 mTorr)

During deposition, as shown in FIG. 6, the back of the silicon substrate 1 is absorbed and chucked by an electrostatic chuck 51, which is provided in a reaction chamber of a HDP-CVD apparatus. In the electrostatic chuck 51, a number of vents are provided along two circumferences having different diameters. Helium (He) for cooling is blown to the back of the silicon substrate 1 through these vents 52 to cool the silicon substrate 1, and deposition temperature (substrate temperature) is set to a desirable temperature in the range from 400 to 680° C. In case of setting deposition temperature to 500° C., for example, the He pressure of the vents 52 on the inner periphery is 2.7 Pa (2 Torr), and that of the vents 52 on the outer periphery is 6.7 Pa (5 Torr). The vents 52 are divided in the inner periphery and the outer periphery in order to keep the substrate temperature, that is, the deposition temperature uniform in the surface.

As shown in FIG. 3, the silicon oxide film 8 is polished and flattened by chemical mechanical polishing (CMP) method, for example.

A resist pattern (not shown) used for forming contact holes is formed on the silicon oxide film 8 by lithography, the silicon oxide film 8 and the silicon nitride film 7 are etched by RIE method using the resist pattern as a mask, and a contact hole 9 is formed on the drain region 6. After that, resist pattern and etching residue are removed by ashing.

The pretreatment by the wet etching using hydrofluoric acid is performed, and native oxide (not shown) is removed from the surface of the drain region 6 at the bottom portion of the contact hole 9.

As shown in FIG. 5, after the polycrystalline silicon film 10 has been deposited on the entire substrate surface and the contact hole 9 has been buried by low pressure CVD method, for example, the polycrystalline silicon film 10 is changed to be n⁺-type by doping phosphor (P) by ion implantation.

After that, a desirable DRAM is manufactured through necessary processes such as formation of a metal wiring.

Compared in FIG. 7 are Q_{bd} evaluation result of the silicon oxide film 8 deposited by HDP-CVD method under a deposition condition according to the embodiment of this invention (deposition temperature is 400° C.), that of a silicon oxide film deposited by O₃-TEOS CVD method, and that of a silicon oxide film deposited by HDP-CVD method under a conventional deposition condition. A capacitor TEG having a structure as shown in FIG. 8 was used for the evaluation. In the capacitor TEG, the area of a gate electrode is 1000 times as large as that of a gate oxide film. As to the He pressure for cooling applied to the silicon substrate 1, in case deposition temperature is 400° C., the pressure of 5.3 Pa (4 Torr) is applied to the vents 52 on the inner periphery, and the pressure of 10.7 Pa (8 Torr) is applied to the vents 52 on the outer periphery. Other deposition conditions are same as those of the silicon oxide film 8 according to the embodiment. As is specific from FIG. 7, the obtained Q_{bd} evaluation result of the silicon oxide film 8 deposited at a deposition temperature in the range from 400 to 680° C. according to the embodiment is remarkably improved compared with that of the silicon oxide film deposited at 700° C. by HDP-CVD method under the conventional deposition condition, and is equal with that of the silicon oxide film deposited by O₃-TEOS CVD method. Therefore, PID of the silicon oxide film 8 is remarkably improved compared with the silicon oxide film deposited by the HDP-CVD method under the conventional deposition condition, and its reliability is excellent. Though a detailed description is omitted, it has been confirmed that a same result is obtained as to the silicon oxide film 8 deposited by HDP-CVD method at a deposition temperature of 500° C.

As described above, according to the embodiment, since deposition temperature is set in the range from 400 to 680° C. during deposition of the silicon oxide film 8 as an interlayer insulating film by HDP-CVD method, it is possible to effectively control the generation of PID on the silicon oxide film 8 during deposition and to obtain the silicon oxide film 8 having an excellent reliability. Since the silicon oxide film 8 with substantially reduced PID can be obtained, it is possible to reduce variation of threshold voltage of p-channel MOS transistor, to remarkably reduce the degradation of characteristics of the device, and to improve a manufacturing yield rate of DRAM. In addition, since the silicon oxide film 8 is excellent in quality, it is possible to control the wet etching rate low and to prevent the contact hole 9 from expanding caused by hydrofluoric acid during the pretreatment.

Thus, according to the embodiment, it is possible to control the expansion of the contact hole 9 caused by a hydrofluoric acid process in the pretreatment prior to a burying process performed after the contact hole 9 has been formed on the silicon oxide film 8 that is deposited by HDP-CVD method, and to improve the reliability of the silicon oxide film 8 by controlling its PID, and to remarkably reduce variation of threshold voltage of a p-channel MOS transistor.

Although an embodiment of the invention has been specifically explained above, the present invention is not limited to the above-described embodiment, but includes various changes based on the technical idea of the invention.

For example, numerical values, materials, structures, shapes, source gases and the like are merely examples, and any other appropriate numerical values, materials, structures, shapes, and source gases may be used in accordance with the demand.

In the above-described embodiment, the silicon substrate is chucked by using the electrostatic chuck as shown in FIG. 6, and deposition temperature is set to a desirable temperature by blowing He for cooling to the silicon substrate from the back of it. However, deposition temperature may be set by another method. Furthermore, the silicon substrate may be kept in another method.

In the above-described embodiment, though O₂ is used as oxygen source gas during deposition of the silicon oxide film 8, for example N₂O may be used as oxygen source gas.

As described above, according to the invention, since deposition temperature is set in the range from 400 to 680° C. during deposition of an insulating film mainly consisting of a silicon oxide by high density plasma CVD method, in processes thereafter, it is possible to prevent the expansion of the contact holes caused by a hydrofluoric acid process in the pretreatment prior to a burying process that is performed after the contact holes have been formed in the insulating film, and to control PID of the insulating film and improve its reliability.

In addition, according to the invention, since deposition temperature is set in the range from 300 to 680° C. during deposition of an insulating film mainly consisting of a silicon oxide by high density plasma CVD method, after contact holes have been formed in the insulating film, it is possible to control degassing from sidewall of the contact holes and to control PID of the insulating film and improve its reliability.

The present invention is the most effective in the application to a device which is progressed in refining to level of channel length of 0.13 μm or less in a MOS device. This is because when high density plasma CVD is performed in a device which is more refined than this level, bad influence of PID on device characteristics causes a problem.

1. A depositing method of an insulating film for depositing an insulating film mainly consisting of a silicon oxide by a high density plasma CVD method,
wherein deposition temperature of said insulating film is set in the range from 400 to 680° C.

2. The depositing method of an insulating film according to claim 1,
wherein deposition temperature of said insulating film is set in the range from 400 to 600° C.

3. The depositing method of an insulating film according to claim 1,
wherein deposition temperature of said insulating film is set in the range from 450 to 550° C.

4. The depositing method of an insulating film according to claim 1,
wherein said insulating film is a silicon oxide film.

5. The depositing method of an insulating film according to claim 1,
wherein said insulating film is a silicate glass film.

6. A depositing method of an insulating film for depositing an insulating film mainly consisting of a silicon oxide by a high density plasma CVD method,
wherein deposition temperature of said insulating film is set in the range from 300 to 680° C.

7. The depositing method of an insulating film according to claim 6,
wherein deposition temperature of said insulating film is set in the range from 360 to 550° C.

8. The depositing method of an insulating film according to claim 6,
wherein said insulating film is a silicon oxide film.

9. The depositing method of an insulating film according to claim 6,
wherein said insulating film is a silicate glass film.

10. A manufacturing method of a semiconductor device, comprising the steps of:
depositing an insulating film mainly consisting of a silicon oxide by a high density plasma CVD method, and
performing the pretreatment to contact holes by wet etching after said contact holes have been formed in said insulating film,
wherein deposition temperature of said insulating film is set in the range from 400 to 680° C.

11. The manufacturing method of a semiconductor device according to claim 10,
wherein deposition temperature of said insulating film is set in the range from 400 to 600° C.

12. The manufacturing method of a semiconductor device according to claim 10,
wherein deposition temperature of said insulating film is set in the range from 450 to 550° C.

13. The manufacturing method of a semiconductor device according to claim 10,
wherein after the pretreatment has been performed to contact holes by wet etching, said contact holes are buried with burying material.

14. The manufacturing method of a semiconductor device according to claim 10,
wherein said insulating film is a silicon oxide film.

15. The manufacturing method of a semiconductor device according to claim 10,
wherein said insulating film is a silicate glass film.

16. A manufacturing method of a semiconductor device, comprising the steps of:
depositing an insulating film mainly consisting of a silicon oxide by a high density plasma CVD method, and
forming contact holes in said insulating film,
wherein deposition temperature of said insulating film is set in the range from 300 to 680° C.

17. The manufacturing method of a semiconductor device according to claim 16,
wherein deposition temperature of said insulating film is set in the range from 360 to 550° C.

18. The manufacturing method of a semiconductor device according to claim 16,
wherein said contact holes are buried with burying material.

19. The manufacturing method of a semiconductor device according to claim 16,
wherein said insulating film is a silicon oxide film.

20. The manufacturing method of a semiconductor device according to claim 16,
wherein said insulating film is a silicate glass film.
